(19) United States
(12) Patent Application Publication
(10) Pub. No.: US 2015/0311139 A1
(43) Pub. Date: Oct. 29, 2015

(54) Method of Packaging Semiconductor Devices and Apparatus for Performing the Same

(71) Applicant: Dongbu Hitek Co., Ltd., Seoul (KR)

(72) Inventors: Jun Il Kim, Gyeonggi-do (KR); Sung Jin Kim, Gyeonggi-do (KR); Hag Mo Kim, Gyeonggi-do (KR)

(21) Appl. No.: 14/496,444

(22) Filed: Sep. 25, 2014

(30) Foreign Application Priority Data
Apr. 24, 2014 (KR) 10-2014-0049058

(51) Int. Cl. H01L 23/373; H01L 21/67; H01L 21/66; H01L 21/56

(52) U.S. Cl. CPC H01L 23/3737; H01L 21/563; H01L 21/561; H01L 21/67126; H01L 21/67259; H01L 22/26

(57) ABSTRACT

Provided are a method and an apparatus for packaging semiconductor devices mounted on a flexible substrate having a longitudinally extending tape shape and defining packaging areas in a longitudinally extending direction along the flexible substrate. The flexible substrate is transferred through a packaging module. An empty area on which a semiconductor device is not mounted is detected from among the packaging areas, and a heat dissipation layer is formed on at least one semiconductor device located in a processing region of the packaging module so as to package the semiconductor device. The heat dissipation layer is formed by coating the semiconductor device with a heat dissipation paint composition, and operations of the packaging module are controlled by a controller to omit a packaging process on the empty area.

### CROSS-REFERENCE TO RELATED APPLICATION

This application claims priority to Korean Patent Application No. 10-2014-0049058 filed on Apr. 24, 2014 and all the benefits accruing therefrom under 35 U.S.C. §119, the contents of which are herein incorporated by reference in their entirety.

### BACKGROUND

The present disclosure relates to methods for packaging semiconductor devices and apparatuses for performing the same, and more particularly, to methods for packaging semiconductor devices mounted on a flexible substrate, such as a chip on film (COF) tape, a tape carrier package (TCP) tape, and the like, and apparatuses for performing the same.

Generally, a display apparatus such as a liquid crystal display (LCD) may include a liquid crystal panel and a backlight unit disposed on a rear of the liquid crystal panel. Semiconductor devices such as driver integrated circuits (IC) may be employed to drive the liquid crystal panel. These semiconductor devices may be connected to the liquid crystal panel using packaging techniques such as COF, TCP, chip on glass (COG), and the like.

High resolution display devices may require an increased driving load to be provided by the semiconductor device. In the particular case of COF-type semiconductor packages, this increased driving load may cause increased heat generation, leading to problems associated with the need for increased heat dissipation.

To address the need for increased heat dissipation, some prior art methods have been developed that involve the addition of a heat sink using an adhesion member. For example, Korean Laid-Open Patent Publication No. 10-2009-0110206 discloses a COF type semiconductor package including a flexible substrate, a semiconductor device mounted on the top surface of the flexible substrate and a heat sink mounted on the bottom surface of the flexible substrate by using an adhesion member.

However, heat sinks mounted on the bottom surface of a flexible substrate may be inefficient due to the relatively low thermal conductivity of the flexible substrate. In addition, such heat sinks typically have a plate shape made by using a metal such as aluminum, which may reduce the flexibility of the COF type semiconductor package. Furthermore, over time and through normal use, the heat sink may become separated from the flexible substrate.

### SUMMARY

The present disclosure provides a packaging method capable of that improves the heat dissipation efficiency of semiconductor devices and an apparatus for performing the same.

In accordance with some exemplary embodiments, a method of packaging semiconductor devices mounted on a flexible substrate having a longitudinally extending tape shape and defining packaging areas along a longitudinally extending direction. The method may include transferring the flexible substrate through a packaging module, detecting an empty area on which a semiconductor device is not mounted from among the packaging areas, and forming a heat dissipation layer on at least one semiconductor device located in a processing region of the packaging module so as to package the semiconductor device. Particularly, the heat dissipation layer may be formed by coating the semiconductor device with a heat dissipation paint composition. A packaging process may be omitted on the empty area.

In some exemplary embodiments, the heat dissipation layer may be formed by a potting process.

In some exemplary embodiments, the forming of the heat dissipation layer may include forming a first heat dissipation layer by coating the heat dissipation paint composition on at least one side surface of the semiconductor device and at least a portion of the flexible substrate, and forming a second heat dissipation layer by coating the heat dissipation paint composition on at least a portion of a top surface of the semiconductor device.

In some exemplary embodiments, a plurality of packaging areas may be located in the processing region of the packaging module, and semiconductor devices mounted on the remaining areas of the packaging areas located in the processing region of the packaging module may be packaged at the same time, except for the empty area.

In some exemplary embodiments, the method may further include curing the heat dissipation layer formed on the semiconductor device.

In some exemplary embodiments, the method may further include forming an underfill layer between the flexible substrate and the semiconductor device.

In some exemplary embodiments, the underfill layer may be formed by injecting an underfill resin into a space defined between the flexible substrate and the semiconductor device.

In some exemplary embodiments, the forming of the underfill layer may include transferring the flexible substrate through an underfill module prior to transferring the flexible substrate through the packaging module, and forming the underfill layer between the packaging area of the flexible substrate and the semiconductor device located in a processing region of the underfill module. An underfill process may be omitted on the empty area.

In some exemplary embodiments, a plurality of packaging areas may be located in the processing region of the underfill module, and underfill processes on the semiconductor devices mounted on the remaining areas of the packaging areas located in the processing region of the underfill module may be performed at the same time, except in the empty area.

In some exemplary embodiments, the method may further include curing the underfill layer.

In some exemplary embodiments, the heat dissipation paint composition may include approximately 1 wt % to approximately 5 wt % of an epichlorohydrin bisphenol A resin, approximately 1 wt % to approximately 5 wt % of a modified epoxy resin, approximately 1 wt % to approximately 10 wt % of a curing agent, approximately 1 wt % to approximately 5 wt % of a curing accelerator and the remaining amount of the heat dissipation paint composition may comprise a heat dissipation filler.

In exemplary embodiments, the modified epoxy resin may include a carboxyl terminated butadiene acrylonitrile (CTBN) modified epoxy resin, an amine terminated butadiene acrylonitrile (ATBN) modified epoxy resin, a nitrile butadiene rubber (NBR) modified epoxy resin, acrylic rubber modified epoxy resin (ARMER), an urethane modified epoxy resin or a silicon modified epoxy resin.

In exemplary embodiments, the curing agent may be a novolac type phenolic resin.

In exemplary embodiments, the curing accelerator may include an imidazole-based curing accelerator or an amine-based curing accelerator.

In exemplary embodiments, the heat dissipation filler may include aluminum oxide having a particle size in a range between approximately 0.01 μm to approximately 50 μm.

In accordance with another exemplary embodiment, an apparatus for packaging semiconductor devices mounted on a flexible substrate having a longitudinally extending tape shape and defining packaging areas along an extending direction thereof may include an unwinder module configured to supply the flexible substrate, a rewinder module configured to recover the flexible substrate, a packaging module disposed between the unwinder module and the rewinder module and configured to coat the semiconductor devices with a heat dissipation paint composition so as to form heat dissipation layers packaging the semiconductor devices, and a controller configured to control operations of the packaging module to detect an empty area on which a semiconductor device is not mounted from among the packaging areas and to omit a packaging process on the empty area.

In some exemplary embodiments, the packaging module may include a packaging chamber. The packaging module may also include a potting unit disposed in the packaging chamber and configured to coat the semiconductor devices with the heat dissipation paint composition. The packaging module may also include a packaging driving unit configured to move the potting unit in at least one of vertical or horizontal direction.

In some exemplary embodiments, the apparatus may further include a curing module configured to cure the heat dissipation layers.

In some exemplary embodiments, the curing module may include a curing chamber disposed between the packaging module and the rewinder module and a plurality of heaters disposed along a transfer path of the flexible substrate in the curing chamber and configured to cure the heat dissipation layers.

In exemplary embodiments, the apparatus may further include an underfill module configured to form underfill layers between the flexible substrate and the semiconductor devices.

The above summary is provided merely for purposes of summarizing some example embodiments to provide a basic understanding of some aspects of the invention. Accordingly, it will be appreciated that the above-described embodiments are merely examples and should not be construed to narrow the scope or spirit of the invention in any way. It will be appreciated that the scope of the invention encompasses many potential embodiments in addition to those here summarized, some of which will be further described below.

### BRIEF DESCRIPTION OF THE DRAWINGS

Exemplary embodiments can be understood in more detail from the following description taken in conjunction with the accompanying drawings, in which:

FIG. 1 depicts a schematic configuration diagram of an apparatus appropriate for performing a method of packaging semiconductor devices according to some exemplary embodiments;

FIG. 2 depicts a schematic configuration diagram of a flexible substrate as shown in FIG. 1 in accordance with some exemplary embodiments;

FIG. 3 depicts a schematic configuration diagram of a packaging module as shown in FIG. 1 in accordance with some exemplary embodiments;

FIGS. 4 to 6 depict schematic cross-sectional views illustrating the method of packaging semiconductor devices in accordance with some exemplary embodiments;

FIGS. 7 and 8 depict photographic images of a semiconductor package manufactured by a method as shown in FIGS. 4 to 6 in accordance with some exemplary embodiments;

FIG. 9 depicts a schematic configuration diagram of an apparatus appropriate for performing a method of packaging semiconductor devices according to some exemplary embodiments; and

FIGS. 10 to 11 depict schematic cross-sectional views illustrating a method of packaging semiconductor devices of as illustrated in FIG. 9 in accordance with some exemplary embodiments.

### DETAILED DESCRIPTION OF EMBODIMENTS

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

It will also be understood that when a layer, a film, a region or a plate is referred to as being ‘on’ another layer, film, region, or plate, it can be directly on the other one, or one or more intervening layers, films, regions or plates may also be present. Otherwise, when an element is referred to as being directly on another element, no intervening elements may be present. It will be understood that, although ordinal numbers such as first, second, third etc. may be used herein to describe various elements, components, regions, layers and/or sections, these terms are used merely for ease of reference and/or antecedent basis for particular elements, regions, layers, and/or sections. Accordingly, these terms should not be construed to describe of imply a particular sequence or ordering of elements, components, regions, layers and/or sections unless explicitly stated.

The terminology used herein is for the purpose of describing particular example embodiments only and is not intended to limit the present inventive concept. Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments are described herein with reference to schematic illustrations of idealized example embodiments. Variations from the sizes and shapes of the illustrations as a result, for example, of manufacturing techniques and/or tolerances, are to be expected. Furthermore, these schematics are not drawn to scale. Thus, example embodiments should not be construed as limited to the particular sizes or shapes of regions illustrated herein. These example embodiments may include deviations in shapes that result, for example, from manufacturing. As such, it should be appreciated that the regions illustrated in the figures are not intended to illustrate the actual size or shape of a region of a device and are not intended to limit the scope of the present inventive concept or claims.

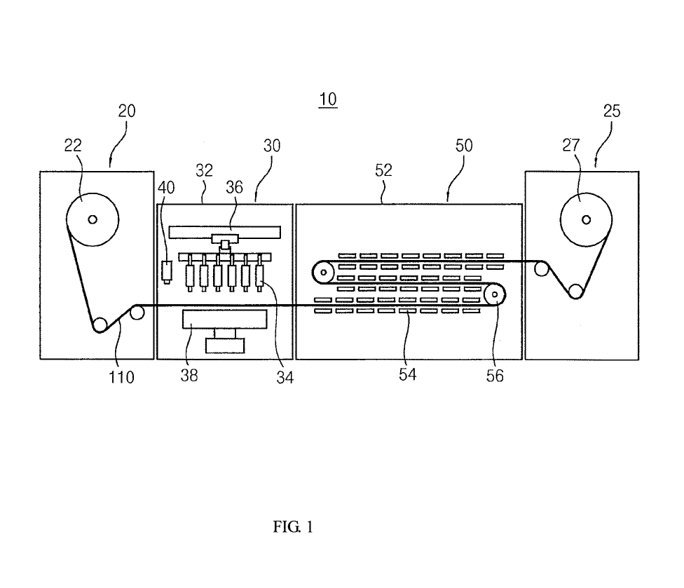

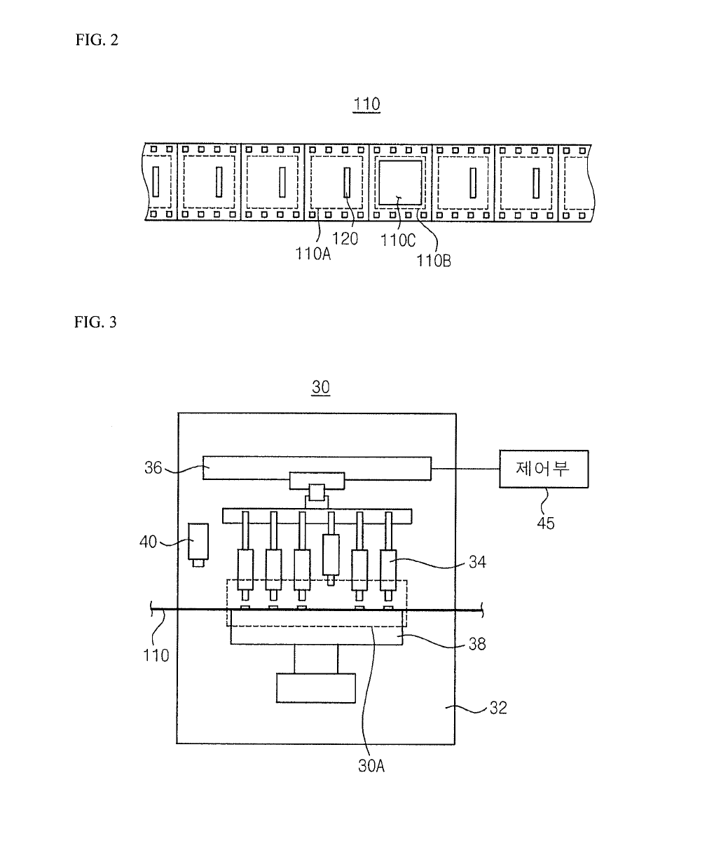

FIG. 1 depicts a schematic diagram of an apparatus 10 for performing a method of packaging semiconductor devices 120 in accordance with some exemplary embodiments. FIG. 2 depicts a schematic diagram of a flexible substrate 110, embodiments of which are described with respect to in FIG. 1. FIG. 3 depicts a schematic diagram of a packaging module 30, example embodiments of which are described with respect to in FIG. 1.

As depicted in FIGS. 1-3, the apparatus 10 for packaging the semiconductor devices 120 may be used to package the semiconductor devices 120 mounted on the flexible substrate 110. Particularly, the flexible substrate 110 may, for example, be a chip on film (COF) tape used as part of a manufacturing process to construct COF semiconductor packages. As additional examples, the flexible substrate 110 may a tape carrier package (TCP) tape, a ball grid array (BGA) tape, or an application specific integrated circuit (ASIC) tape.

The flexible substrate 110 may have a longitudinally extending tape shape, and, as shown in FIG. 2, a plurality of packaging areas 110A may be defined extending along the length the flexible substrate 110. The semiconductor devices 120 may be mounted on the packaging areas 110A by, for example, a die-bonding process.

After performing the die-bonding process, the semiconductor devices 120 mounted on the flexible substrate 110 may be inspected via an inspection process. Semiconductor devices determined to be defective may be removed from the flexible substrate 110 as a result of the inspection process. For example, defective semiconductor devices may be removed from the flexible substrate 110 by a “punching” process. As a result, the flexible substrate 110, may include one or more empty areas 110B on which the semiconductor device is not mounted due to removal of semiconductor devices during the inspection process. As a result of the “punching” process, a punch hole 110C may be formed in the empty area 110B.

The packaging apparatus 10 may include an unwinder module for supplying the flexible substrate 110 and a rewinder module 25 for recovering the flexible substrate 110. The unwinder module 20 and the rewinder module 25 may include a supplying reel 22 and a recovering reel 27, respectively, for supplying and recovering the flexible substrate 110. The packaging apparatus may further include driving units (not shown) for rotating the supplying reel 22 and the collecting reel 27.

A packaging module 30 for performing a process of packaging the semiconductor devices 120 may be disposed between the unwinder module 20 and the rewinder module 25. The packaging module 30 may include a packaging chamber 32, and the flexible substrate 110 may be transferred in a horizontal direction (e.g., lengthwise) through the packaging chamber 32.

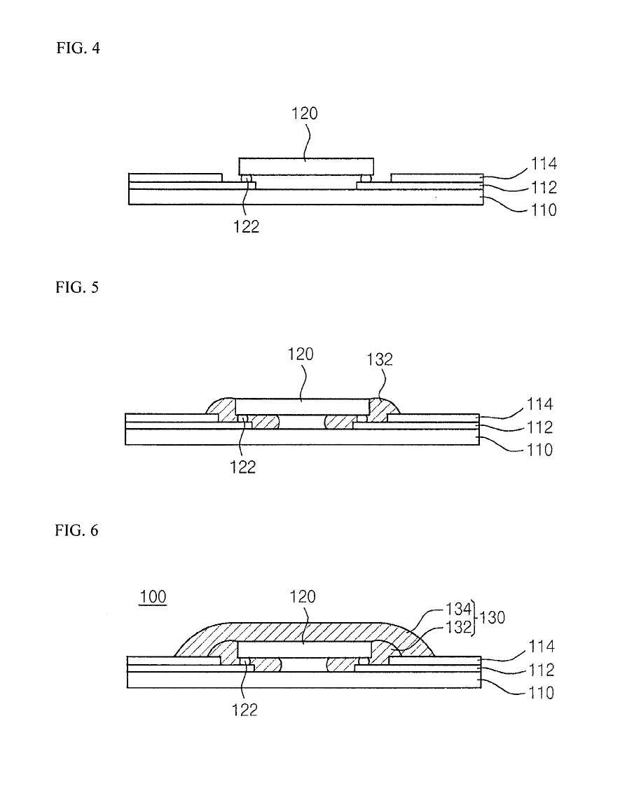

According to some exemplary embodiments, a heat dissipation paint composition may be coated onto the semiconductor devices 120 located in the packaging chamber 32. As a result of this coating process, heat dissipation layers 130 (refer to FIG. 4) may be formed on the semiconductor devices 120, thereby packaging the semiconductor devices 120 on the flexible substrate 110. In some exemplary embodiments, the heat dissipation layers 130 may be formed by a potting process. For example, potting units 34 configured to coat the heat dissipation paint composition on the semiconductor devices 120 may be disposed in the packaging chamber 32.

As shown in the drawings, six potting units 34 may be disposed in the packaging chamber 32. It should be appreciated, however, that the number of potting units 34 depicted is not intended to be limited by the drawings and various numbers of potting units 34 may be employed. For example, some embodiments may only include a single potting unit 34 disposed within the packaging chamber 32.

The potting units 34 may be configured to be movable in vertical and/or horizontal directions by a packaging driving unit 36. For example, although not shown in detail, the packaging driving unit 36 may be a Cartesian coordinate robot configured to move the potting units 34 in the vertical and horizontal directions.

The packaging chamber 32 may include a supporting member 38 for supporting the flexible substrate 110. The supporting member 38 may have a flat top surface, and, as shown in the drawings, the supporting member 38 may partially or fully support the flexible substrate 110 located below the potting units 34. The supporting member 38 may define a plurality of vacuum holes (not shown). The supporting member 38 may, through the use of the plurality of vacuum holes, adsorb and fix a portion of the flexible substrate 110 located on the supporting member 38 using a vacuum. The supporting member 38, although not shown in detail, may be configured to be movable in a vertical direction to support the flexible substrate 110.

A processing region 30A, as depicted in FIG. 3, may be defined to perform the packaging process in the package chamber 32. Particularly, the processing region 30A may be defined between the potting units 34 and the supporting member 38. The potting units 34 may perform a packaging process on the semiconductor devices 120 located in the processing region 30A. For example, as shown in the drawing, six packaging areas 110A may be located in the processing region 30A, and the packaging processes on the semiconductor devices 120 mounted on the six packaging areas 110A may be performed simultaneously.

The packaging process may detect whether an empty area, such as the empty area 110B, is presented among the packaging areas 110A located in the processing region 30A. When an empty area is detected, the packaging process may be performed on packaging areas 110A other than the empty area 110B. The packaging process occurring on the packaging areas 110A may be simultaneous, with the process avoiding performing the process on the empty area 110B.

As depicted in FIG. 3, the packaging driving unit 36 may lower the potting units 34 to be adjacent to the semiconductor devices 120, other than a potting unit disposed over an empty area 110B. The packaging driving unit 36 may move the potting units 34 in the horizontal direction to simultaneously perform the packaging processes on the semiconductor devices 120. The heat dissipation paint composition may be coated on the semiconductor devices 120 by the potting units 34 other than the any potting units 34 disposed over an empty area 110B. As a result of this process, the semiconductor devices 120 may be packaged with the heat dissipation paint composition.

According to the some embodiments, the packaging apparatus 10 may include a camera 40 for detecting the empty area 110B and a controller 45. The controller 45 may control operations of the packaging driving unit 36 and the potting units 34 to omit the packaging process with respect to the empty area 110B. Alternatively, information indicating the empty area 110B may be previously provided to the controller 45. For example, result data of an inspection process on the semiconductor devices 120 and the punching process may be provided to the controller 45 prior to or during the packaging process to enable the controller 45 to skip the empty area(s) 110B during the packaging process. The controller 45 may control the operations of the packaging driving unit 36 and the potting units 34 using the provided data and/or detection data from the camera 40.

The packaging apparatus 10 may include a curing module 50 for curing the heat dissipation layer 130 formed on the semiconductor device 120.

The curing module 50 may include a curing chamber 52. The flexible substrate 110 may be transferred through the curing chamber 52. The curing chamber may include a plurality of heaters 54 disposed along a transfer path for the flexible substrate 110. Additionally, the curing chamber may include rollers 56 configured to adjust a transfer distance, speed, and/or direction of the flexible substrate 110. For example, the flexible substrate 110 may be transferred along a transfer path extending a zigzag in the curing chamber 52. As the flexible substrate 110 is transferred along the transfer path, the heat dissipation layers 130 on the semiconductor devices 120 may be cured by the heaters 54.

Methods for packaging the semiconductor devices according to some exemplary embodiments of the present invention will now be described in further detail with reference to the attached drawings.

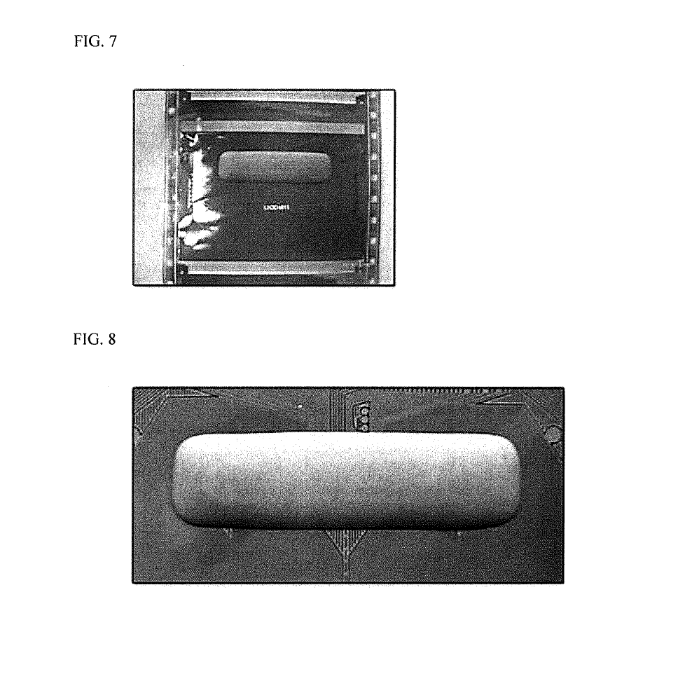

FIGS. 4 to 6 depict schematic cross-sectional views illustrating an embodiment of a method for packaging semiconductor devices. FIGS. 7 and 8 depict illustrations of a semiconductor package manufactured using an embodiment of the method depicted in FIGS. 4 to 6.

The flexible substrate 110 may be transferred between the unwinder module 20 and the rewinder module 25 through the packaging module 30 and the curing module 50, as shown in FIG. 1. As depicted above, the semiconductor devices 120 are mounted on the packaging areas 110A of the flexible substrate 110.

Signal lines 112, such as conductive patterns, may be disposed on the flexible substrate 119. An insulating layer 114 for protecting the signal lines 112 may be disposed on the signal lines 112. The semiconductor devices 120, as shown in FIG. 4, may be bonded to the flexible substrate 110 to be connected to the signal lines 112 through gold bumps and/or solder bumps 122. For example, the signal lines 112 may be formed of conductive material such as copper and the insulating layer 114 may be one of a surface resist (SR) layer or a solder resist layer.

The empty area 110B on which the semiconductor device is not mounted may be detected from among the packaging areas 110A by the camera 40, prior to performing the packaging processes for the semiconductor devices 120 located in the processing region 30A of the packaging module 30. As described above, the controller 45 may control the operations of the packaging module 30 to omit the packaging process on the empty area 110B.

The heat dissipation paint composition may be coated on the semiconductor devices 120 by the potting units 34 in the processing region 30A of the packaging module 30, thereby forming the heat dissipation layers 130 on the semiconductor devices 120.

According to some exemplary embodiments, as shown in FIG. 5, a first heat dissipation layer 132 may be formed by coating heat dissipation paint composition on side surfaces of the semiconductor devices 120 and a top surface portion of the flexible substrate 110 adjacent to the side surfaces of the semiconductor devices 120. As shown in FIG. 6, a second heat dissipation layer 134 may be formed by coating the heat dissipation paint composition on a top surface of the semiconductor device 120.

The packaging driving unit 36 may lower the potting units 34 to be adjacent to the semiconductor devices 120 on the remaining packaging areas 110A except the empty area 110B. The packaging driving unit 36 may move the potting units 34 in a horizontal direction along the side surfaces of the semiconductor devices 120 to form the first heat dissipation layer 132. The packaging driving unit 36 may also move the potting units 34 in a horizontal direction over the semiconductor devices 120 to form the second heat dissipation layer 134.

The heat dissipation paint composition may infiltrate into a space between the flexible substrate 110 and the semiconductor device 120 during the packaging process. However, when the heat dissipation paint composition does not completely infiltrate into the space between the flexible substrate 110 and the semiconductor device 120, an air gap may be formed between the flexible substrate 110 and the semiconductor device 120 as depicted in FIGS. 5 and 6.

According to the some exemplary embodiments, the viscosity of the heat dissipation paint composition may be adjusted to ensure that the heat dissipation paint composition may sufficiently infiltrate into the space between the flexible substrate 110 and the semiconductor device 120. In such cases, an underfill layer may be formed between the flexible substrate 110 and the semiconductor device 120 by the infiltration of the heat dissipation paint composition.

Referring to FIGS. 7 and 8, after forming the heat dissipation layers 130 as described above, the flexible substrate 110 may be transferred into the curing chamber 52 and the heat dissipation layers 130 on the semiconductor devices 120 may be fully cured while being transferred through the curing chamber 52. The heat dissipation layers 130 may be cured at a temperature of from about 140° C. to about 160° C. For example, the heat dissipation layers may be cured at a temperature of about 150° C. The curing process may thereby complete semiconductor packages 100 having improved heat dissipation properties and flexibility.

In accordance with some example embodiments, the heat dissipation paint composition may include an epichlorohydrin bisphenol A resin, a modified epoxy resin, a curing agent, a curing accelerator, a heat dissipation filler, and/or combinations thereof. In particular, in some exemplary embodiments the heat dissipation paint composition may include approximately 1 wt % to approximately 5 wt % of the epichlorohydrin bisphenol A resin, approximately 1 wt % to approximately 5 wt % of the modified epoxy resin, approximately 1 wt % to approximately 10 wt % of the curing agent, approximately 1 wt % to approximately 5 wt % of the curing accelerator and the remaining amount of the heat dissipation filler.

The use of epichlorohydrin bisphenol A resin may improve the adhesiveness of the heat dissipation paint composition, and the use of modified epoxy resin may improve the flexibility and the elasticity of the heat dissipation layer during and after the curing process. Particularly, the modified epoxy resin may include a carboxyl terminated butadiene acrylonitrile (CTBN) modified epoxy resin, an amine terminated butadiene acrylonitrile (ATBN) modified epoxy resin, a nitrile butadiene rubber (NBR) modified epoxy resin, an acrylic rubber modified epoxy resin (ARMER), an urethane modified epoxy resin, a silicon modified epoxy resin, and the like.

The curing agent may include a novolac type phenolic resin. For example, a novolac type phenolic resin obtained by reacting one of phenol, cresol and bisphenol A with formaldehyde may be used.

The curing accelerator may include an imidazole-based curing accelerator or an amine-based curing accelerator. For example, the imidazole-based curing accelerator may include imidazole, isoimidazole, 2-methylimidazole, 2-ethyl-4-methylimidazole, 2,4-dimethylimidazole, butylimidazole, 2-methylimidazole, 2-phenylimidazole, 1-benzyl-2-methylimidazole, 1-propyl-2-methylimidazole, 1-cyanoethyl-2-methylimidazole, 1-cyanoethyl-2-ethyl-4-methylimidazole, phenylimidazole, benzylimidazole, and the like, and combinations thereof.

The amine-based curing accelerator may include an aliphatic amine, a modified aliphatic amine, an aromatic amine, a secondary amine, a tertiary amine, and the like, and combinations thereof. For example, the amine-based curing accelerator may include benzyldimethylamine, triethanolamine, triethylenetetramine, diethylenetriamine, triethylamine, dimethylaminoethanol, m-xylenediamine, isophorone diamine, and the like.

The heat dissipation filler may include aluminum oxide having a particle size of approximately 0.01 μm to approximately 50 μm, and preferably, of approximately 0.01 μm to approximately 20 μm. The heat dissipation filler may be used to improve the thermal conductivity of the cured heat dissipation layer 130. Particularly, the heat dissipation paint composition may include approximately 75 wt % to approximately 95 wt % of the heat dissipation filler based on the total amount of the heat dissipation paint composition. The thermal conductivity of the heat dissipation layer 130 may be adjusted to be within a range of approximately 2.0 W/mK to approximately 3.0 W/mK. In addition, the adhesiveness of the heat dissipation layer 130 may be adjusted to be within a range of approximately 8 MPa and approximately 12 MPa by the epichlorohydrin bisphenol A resin and the modified epoxy resin.

The viscosity of the heat dissipation paint composition may be adjusted to be within a range of approximately 100 Pas to approximately 200 Pas, and the heat dissipation paint composition may be cured in a temperature range of approximately 140° C. to approximately 160° C. The viscosity of the heat dissipation paint composition may be measured by using a B type rotational viscometer and may be particularly measured at a rotor rotation velocity of approximately 20 rpm at a temperature of approximately 23° C.

In accordance with some exemplary embodiments, the heat dissipation layer 130 may be formed directly on the top surface and the side surfaces of the semiconductor device 120, thereby improving and the heat dissipation efficiency from the semiconductor device 120. Since the heat dissipation layer 130 has improved flexibility and adhesiveness, the likelihood of separation of the heat dissipation layer 130 from the flexible substrate 110 and the semiconductor device 120 may be reduced. Also, the flexibility of the semiconductor package 100 may be largely improved when compared to conventional packaging and heat dissipation techniques.

By detecting the presence of an empty area 110B among the packaging areas 110A, embodiments may avoid conducting the packaging process on these empty areas. As a result, embodiments may improve the productivity of the packaging process.

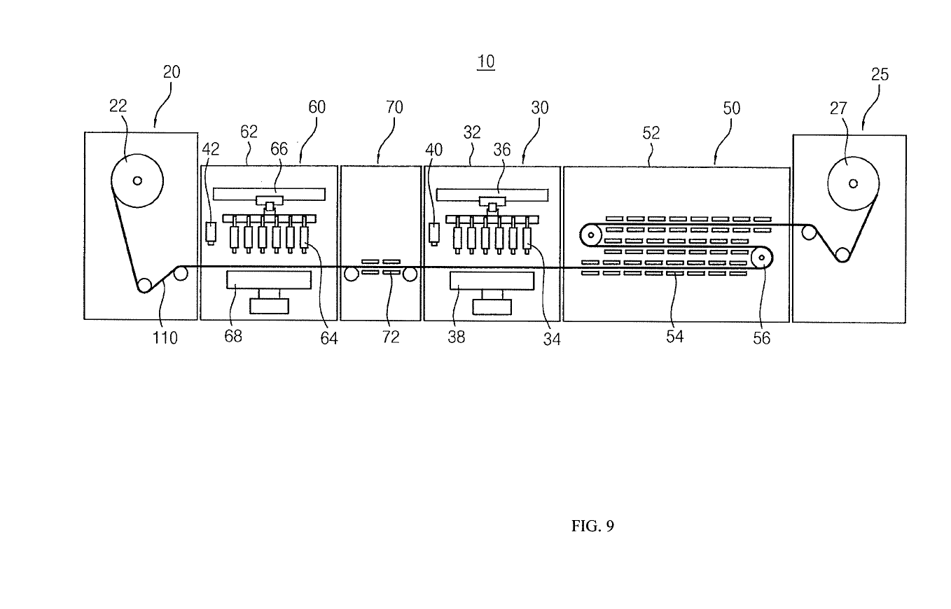

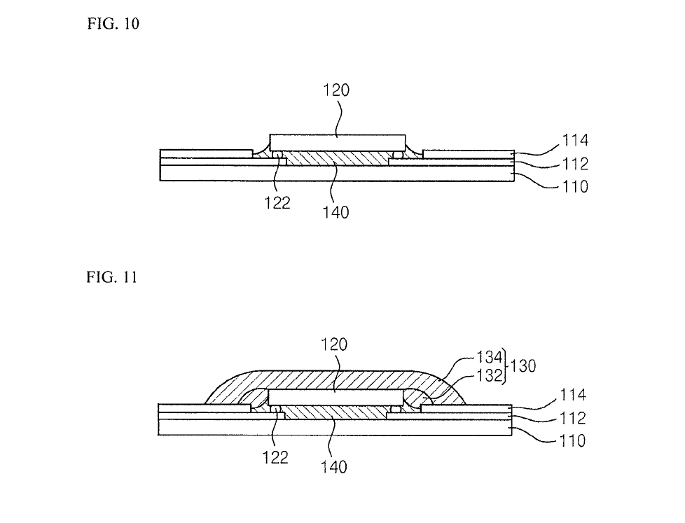

FIG. 9 depicts a schematic diagram of an apparatus for performing a method of packaging semiconductor devices according to some exemplary embodiments. FIGS. 10 to 11 depict schematic cross-sectional views illustrating embodiments of methods for packaging semiconductor devices of FIG. 9.

Turning to FIG. 9, an apparatus 10 for packaging semiconductor devices may include an underfill module 60 for forming an underfill layer 140 (see FIG. 11, below) between the flexible substrate 110 and the semiconductor device 120. The apparatus 10 may also include a pre-curing module 70 for curing the underfill layer 140. The underfill module 60 and the pre-curing module 70 may be disposed between the unwinder module 20 and the packaging module 30. The flexible substrate 110 may be transferred to the packaging module 30 through the underfill module 60 and the pre-curing module 70.

The underfill module 60 may include an underfill chamber 62. The underfill chamber 62 may include potting units 64 for injecting underfill resin into a space between the flexible substrate 110 and the semiconductor devices 120. The potting units 64 may be configured to be movable in vertical and horizontal directions by an underfill driving unit 66.

Furthermore, the apparatus 10 may include a supporting member 68 for supporting the flexible substrate 110 may be disposed in the underfill chamber 62. Although not shown in the drawing, the supporting member 68 may include vacuum holes for adsorbing and fixing the flexible substrate 110 to the supporting member 68. A processing region (not shown) for performing underfill processes therein may be defined in the underfill chamber 62. The processing region may be defined between the potting units 64 and the supporting member 68. The underfill processes may be performed simultaneously on the semiconductor devices 120 located in the processing region.

A camera 42 may be disposed in the underfill chamber 62. This camera 42 may detect the empty area 110B from the packaging areas 110A of the flexible substrate 110. Operations of the underfill driving unit 66 and the potting units 64 may be controlled by the controller 45, and, more particularly, may be controlled to omit the underfill process on the empty area 110B.

As described above, the underfill module 60 may be configured similarly to the packaging module 30. According to some exemplary embodiments, the number of potting units 64 of the underfill module 60 may varied. However, in some embodiments, to improve the productivity of the semiconductor packages 100, the number of the potting units 64 may be identical to the number of potting units 34 of the packaging module 30.

After performing the underfill process through the underfill module 60, the flexible substrate 110 may be transferred to the packaging module 30 through the pre-curing module 70. The pre-curing module 70 may include a heater 72 for curing the underfill layer 140.

Referring to FIG. 10, the potting units 64 may supply the underfill resin to a top surface portion of the flexible substrate 110 adjacent to the side surfaces of the semiconductor devices 120. The underfill resin may infiltrate into a space between the flexible substrate 110 and the semiconductor device 120 due to surface tension. The underfill layer 140 formed between the flexible substrate 110 and the semiconductor device 120 as described above may be cured at a temperature of approximately 150° C. while the flexible substrate passes through the pre-curing module 70.

The underfill resin may include an epoxy resin, a curing agent, a curing accelerator, an inorganic filler, and combinations thereof. The epoxy resin may include a bisphenol A type epoxy resin, a bisphenol F type epoxy resin, a bisphenol S type epoxy resin, a naphthalene type epoxy resin, a phenol novolac type epoxy resin, a cresol novolac epoxy resin, and the like, and combinations thereof. An amine-based curing agent and an imidazole-based curing accelerator may be used as the curing agent and the curing accelerator, respectively.

Aluminum oxide may be used as the inorganic filler to improve the thermal conductivity of the underfill layer 140. The aluminum oxide may have a particle size in a range between approximately 0.01 μm to approximately 20 μm.

Referring to FIG. 11, after forming the underfill layer 140 as described above, the heat dissipation layer 130 may be formed on the semiconductor device 120 and the flexible substrate 110. Since an example of a method of forming the heat dissipation layer 130 has already been described above with reference to FIGS. 4 to 6, additional detailed descriptions thereof will be omitted.

The underfill process using the underfill resin may be performed after a die-bonding process mounts the semiconductor devices 120 onto the flexible substrate 110. In such a case, the semiconductor devices 120 may be packaged using the packaging apparatus and method described above with reference to FIGS. 1 to 6.

According to exemplary embodiments as described above, the heat dissipation layer 130 for dissipating heat generated from the semiconductor device 120 may be formed on the flexible substrate 110 and the semiconductor device 120. The semiconductor device 120 may be packaged by the heat dissipation layer 130. As noted above, the packaging process may be omitted on the empty area 110B of the flexible substrate 110, since a semiconductor device is not mounted in the empty area. Accordingly, the productivity of the packaging process for creating the flexible semiconductor package 100 may be greatly improved.

The heat dissipation layer 130 may improve in flexibility and adhesion due to the epichlorohydrin bisphenol A resin and the modified epoxy resin, and may have relatively higher thermal conductivity due to the heat dissipation filler. Accordingly, the heat dissipation efficiency from the semiconductor device 120 may be greatly improved by the heat dissipation layer 130. Particularly, since the heat dissipation layer 130 has improved flexibility and adhesion, the likelihood of a separation of the heat dissipation layer 130 from the flexible substrate 110 and the semiconductor 120 may be reduced while maintaining the flexibility of the flexible substrate 110.

Additionally, the underfill layer 140 may be formed with an improved thermal conductivity between the flexible substrate 110 and the semiconductor device 120, thereby more increasing the efficiency of heat dissipation from the semiconductor device 120.

Although methods and apparatuses for packaging semiconductor devices have been described with reference to the specific embodiments, it should be appreciated that they are not limited thereto. Therefore, it will be readily understood by those skilled in the art that various modifications and changes can be made thereto without departing from the spirit and scope of the present invention defined by the appended claims.

What is claimed is:

1. A method of packaging semiconductor devices mounted on a flexible substrate having a longitudinally extending tape shape and defined with packaging areas along an extending direction thereof, the method comprising:
transferring the flexible substrate through a packaging module;
detecting, among the packaging areas, an empty area on which a semiconductor device is not mounted; and
forming a heat dissipation layer on at least one semiconductor device located in a processing region of the packaging module so as to package the semiconductor device,
wherein the heat dissipation layer is formed by coating the semiconductor device with a heat dissipation paint composition and wherein a packaging process is omitted on the empty area.

2. The method of claim 1, wherein the heat dissipation layer is formed by a potting process.

3. The method of claim 2, wherein the foiming of the heat dissipation layer comprises:
forming a first heat dissipation layer by coating the heat dissipation paint composition on at least one side surface of the semiconductor device and at least a portion of the flexible substrate; and
forming a second heat dissipation layer by coating the heat dissipation paint composition on at least a portion of a top surface of the semiconductor device.

4. The method of claim 1, wherein a plurality of packaging areas is located in the processing region of the packaging module, and wherein semiconductor devices mounted on the remaining areas of the packaging areas located in the processing region of the packaging module, except the at least one empty area, are packaged at the same time.

5. The method of claim 1, further comprising curing the heat dissipation layer formed on the semiconductor device.

6. The method of claim 1, further comprising forming an underfill layer between the flexible substrate and the semiconductor device.

7. The method of claim 6, wherein the underfill layer is formed by injecting an underfill resin into a space defined between the flexible substrate and the semiconductor device.

8. The method of claim 6, wherein the forming of the underfill layer comprises:
transferring the flexible substrate through an underfill module prior to transferring the flexible substrate through the packaging module; and
forming the underfill layer between the packaging area of the flexible substrate and the semiconductor device located in a processing region of the underfill module,
wherein forming of the underfill layer is omitted on the empty area .

9. The method of claim 8, wherein a plurality of packaging areas is located in the processing region of the underfill module, and wherein underfill processes on semiconductor devices mounted on the remaining areas of the packaging areas located in the processing region of the underfill module are performed at the same time, except for the empty area.

10. The method of claim 6, further comprising curing the underfill layer.

11. The method of claim 1, wherein the heat dissipation paint composition comprises approximately 1 wt % to approximately 5 wt % of an epichlorohydrin bisphenol A resin, approximately 1 wt % to approximately 5 wt % of a modified epoxy resin, approximately 1 wt % to approximately 10 wt % of a curing agent, approximately 1 wt % to approximately 5 wt % of a curing accelerator and the remaining amount of the composition is comprised of a heat dissipation filler.

12. The method of claim 11, wherein the modified epoxy resin comprises a carboxyl terminated butadiene acrylonitrile (CTBN) modified epoxy resin, an amine terminated butadiene acrylonitrile (ATBN) modified epoxy resin, a nitrile butadiene rubber (NBR) modified epoxy resin, acrylic rubber modified epoxy resin (ARMER), an urethane modified epoxy resin or a silicon modified epoxy resin.

13. The method of claim 11, wherein the curing agent is a novolac type phenolic resin.

14. The method of claim 11, wherein the curing accelerator is an imidazole-based curing accelerator or an amine-based curing accelerator.

15. The method of claim 11, wherein the heat dissipation filler comprises aluminum oxide having a particle size within a range of approximately 0.01 μm to approximately 50 μm.

16. An apparatus for packaging semiconductor devices mounted on a flexible substrate having a longitudinally extending tape shape and defined with packaging areas along a longitudinally extending direction thereof, the apparatus comprising:
an unwinder module configured to supply the flexible substrate;
a rewinder module configured to recover the flexible substrate;
a packaging module disposed between the unwinder module and the rewinder module and configured to coat the semiconductor devices with a heat dissipation paint composition so as to form heat dissipation layers packaging the semiconductor devices; and
a controller configured to control operations of the packaging module to detect, among the packaging areas, an empty area on which a semiconductor device is not mounted and to omit a packaging process on the empty area.

17. The apparatus of claim 16, wherein the packaging module comprises:
a packaging chamber;
a potting unit disposed in the packaging chamber, the potting unit configured to coat the semiconductor devices with the heat dissipation paint composition; and
a packaging driving unit configured to move the potting unit in at least one of a vertical direction or a horizontal direction.

18. The apparatus of claim 16, further comprising a curing module configured to cure the heat dissipation layers.

19. The apparatus of claim 18, wherein the curing module comprises:
a curing chamber disposed between the packaging module and the rewinder module; and
a plurality of heaters disposed along a transfer path of the flexible substrate in the curing chamber, the plurality of heaters configured to cure the heat dissipation layers.

20. The apparatus of claim 16, further comprising an underfill module configured to form underfill layers between the flexible substrate and the semiconductor devices.
